(19) United States
(12) Patent Application Publication
(10) Pub. No.: US 2025/0226176 A1
(43) Pub. Date: Jul. 10, 2025

(54) ELECTRICAL ISOLATION OF GAS FEED FOR ION BEAM SYSTEM

(71) Applicant: VEECO INSTRUMENTS INC., Plainview, NY (US)

(72) Inventors: Mohammad SAGHAYEZHIAN, Plainview, NY (US); Binyamin RUBIN, Plainview, NY (US); Kirill GUTSOL, Plainview, NY (US)

(21) Appl. No.: 19/012,247

(22) Filed: Jan. 7, 2025

Related U.S. Application Data
(60) Provisional application No. 63/618,830, filed on Jan. 8, 2024.

(51) Int. Cl. H01J 37/30

(52) U.S. Cl. CPC H01J 37/3007; H01J 2237/006

(57) ABSTRACT

A gas inlet for a high voltage ion beam system, the gas inlet providing an insulating barrier between the high voltage components to which the gas is supplied and the grounded gas supply lines. The gas inlet inhibits electrical breakdown of the system by inhibiting energized particles, or plasma, from contacting the grounded gas supply lines. The gas inlet maximizes the path length to the grounded gas supply line, has electrically insulating material in the path with a designed gas conductance path, and utilizes a transverse magnetic field.

### CROSS-REFERENCE

This application claims priority to U.S. provisional application No. 63/618,830 filed Jan. 8, 2024, the entire disclosure of which is incorporated herein by reference for all purposes.

### BACKGROUND

Ion beam deposition (IBD) is one of many methods suitable for forming thin films, the other methods including (but not limited to) magnetron sputtering, chemical vapor deposition (CVD), and molecular beam epitaxy (MBE). Ion Beam Etch (IBE) is one of the methods used to remove and shape layers of material on the substrate. IBD and IBE systems are used during a fabrication of thin film devices, such as semiconductor or date storage devices, and in other thin film applications. These systems utilize plasma to form and shape the thin films.

For IBD and IBE, ion beams are formed by ions extracted from an ion source that typically includes an ionization chamber connected to an assembly of grids which are connected to negative or positive high-voltage power supplies. A source of desired ion species is introduced into the ionization chamber as a feed material, usually a feed gas, where it is ionized to generate plasma. The plasma potential is defined by the voltage applied to the grid closest to plasma.

### SUMMARY

The present disclosure describes electrical isolation of the gas inlet for ion sources, such as ion beam deposition or etch systems. The gas inlets described herein provide an insulating barrier between the high voltage components to which the gas is supplied and the grounded gas supply lines.

In one particular implementation, this disclosure describes a high-potential gas isolator for an ion beam system, the gas isolator having an electrically insulating body having a first end and an opposite second end with a flow path from the first end to the second end, the flow path extending through an aperture array region having a plurality of axially offset apertures, a magnetized region, and a tortuous path region, with the magnetized region operably in the flow path between the aperture array region and the tortuous path region.

In another particular implementation, this disclosure describes a high-potential gas isolator for an ion beam system, the gas isolator having an electrically insulating body having a first grounded end and a second high potential end with a longitudinal flow path through the body. The flow path extends through an aperture array region having a plurality of longitudinally spaced and axially offset apertures, a magnetized region, and a tortuous path region.

This Summary is provided to introduce a selection of concepts in a simplified form that are further described below in the Detailed Description. This Summary is not intended to identify key or essential features of the claimed subject matter, nor is it intended to be used to limit the scope of the claimed subject matter. These and various other features and advantages will be apparent from a reading of the following Detailed Description.

### BRIEF DESCRIPTION OF THE DRAWING

FIG. 1 is a schematic side view of a portion of an ion beam deposition and ion beam etch system.

FIG. 2 is an enlarged schematic side view of an ion source and plasma generator of an ion beam deposition and ion beam etch system.

FIG. 3 is an enlarged schematic cross-sectional view of a gas inlet for an ion source or plasma generator of an ion beam system.

FIGS. 4A and 4B are schematic top views of pairs of inlet apertures for a gas inlet.

### DETAILED DESCRIPTION

As indicated above, this disclosure is directed to a gas inlet for a high voltage ion beam deposition or etch system, the gas inlet providing an insulating barrier between the high voltage components to which the gas is supplied and the grounded gas supply lines. The described gas inlets inhibit electrical breakdown of the system by neutralizing the backstreaming charged particles and maintaining a large potential barrier between the plasma and ground, along the gas feed system.

Ion beam deposition (IBD) is a thin film technology with unique features capable of tuning the microstructures of thin films through density, purity, phase, texture control, and grain size growth to attain low resistivity in metals, particularly when used with ion assist, etching or bombardment. Ion Beam Etch (IBE) is a technology used to remove and shape layers of material on the substrate. Fundamentally, in ion beam deposition and etch, a beam of energized ions is directed at a target or a substrate, causing atoms or molecules to be ejected from the target or the substrate surface. Particles sputtered from a target in IBD particles travel to a substrate to form the thin film. The system may be at high voltage (for example, greater than 1000 V).

At these and other voltages, plasma ions fill the deposition chamber, with the majority of ions directed to and impinging on their intended target. If assist ion beam is used, the second ion beam is directed at the substrate being coated with the sputtered material. Some plasma ions, however, move in unintended directions, even coming back toward the ion source.

Described herein are gas inlets into the ion source that provide an electrically insulating barrier and a physical hindrance to inhibit plasma from creating an electrical breakdown, or short, between high voltage and grounded components of the gas supply system.

In the following description, reference is made to the accompanying drawing that forms a part hereof and in which is shown by way of illustration at least one specific implementation. The following description provides additional specific implementations. It is to be understood that other implementations are contemplated and may be made without departing from the scope or spirit of the present disclosure. The following detailed description, therefore, is not to be taken in a limiting sense. While the present disclosure is not so limited, an appreciation of various aspects of the disclosure will be gained through a discussion of the examples, including the figures, provided below. In some instances, a reference numeral may have an associated sub-label consisting of a lower-case letter to denote one of multiple similar components. When reference is made to a reference numeral without specification of a sub-label, the reference is intended to refer to all such multiple similar components.

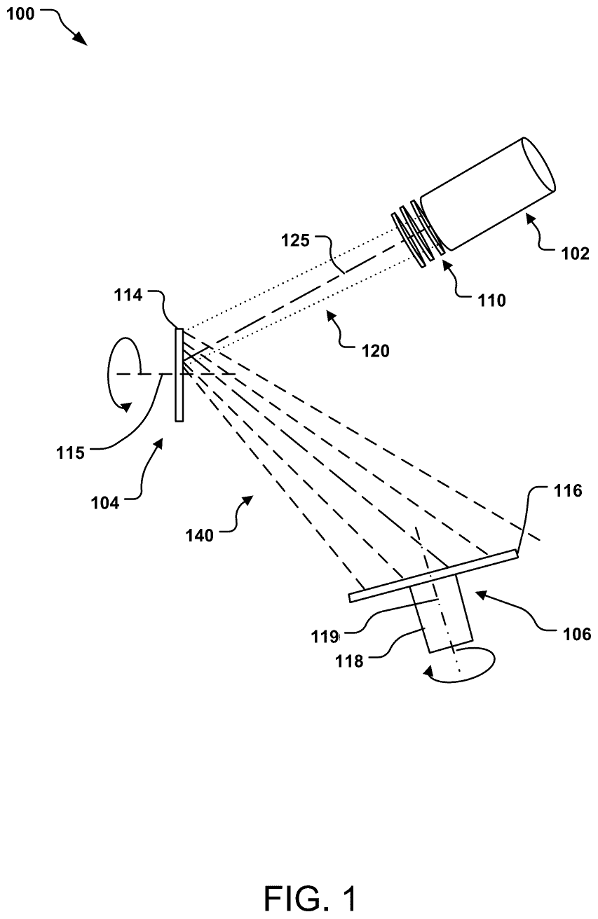

Turning to the figures, FIG. 1 illustrates a generic diagram of an ion beam system 100. Even though the implementation of the ion beam system 100 is shown as an ion beam sputter deposition system, components of the ion beam system 100 may also be used with some alteration for implementing any or all of an ion beam etch system, an ion implantation system, an ion beam deposition system, an ion beam assisted deposition system, etc. The system 100 can be used to, e.g., deposit, deposit and modify, and/or deposit and etch material. Although not shown in FIG. 1, the system 100 includes a process chamber or enclosure in which the components are housed.

The ion beam system 100 includes an ion beam source 102, a target assembly 104, and a substrate assembly 106 for supporting a substrate 116. The substrate assembly 106 may include a single large substrate 116, as shown in FIG. 1, or may include a sub-assembly holder that holds multiple substrates 116 that may be rotatable. The substrate 116 may be, for example, a silicon or glass wafer and/or may have, one or more layers of silicide(s), nitride(s), oxide(s), metal(s) including alloys, or ceramic(s). The ion source 102 may be a DC type, a radio frequency (RF) type or a microwave type gridded or gridless ion source.

The ion beam source 102 generates an ion beam 120 composed of a plurality of ion beamlets targeted or directed toward the target assembly 104, which includes at least one target 114 affixed to the target assembly 104 that includes a material desired to be deposited on the substrate 116.

The ion beam source can include one or more grids 110 for accelerating and directing the ion beam 120 from the ion beam source 102 to the target assembly 104. The grids 110 have a plurality of holes therethrough through which the beamlets pass. The ion beam 120 has a centerline axis 125 that is targeted or directed toward the target 114 such that the ion beam 120 completely or near completely impinges on the target 114. The target 114 is located on a platform of the target assembly 104 that, if needed, can rotate the target 114 about a given axis 115. In some designs, the target 114 may tilt or translate/shift. The ion beam 120, upon striking the target 114, generates a sputter plume 140 of material from the target 114.

Examples of material for the target 114 include, without limitation, metals such as titanium (Ti), tungsten (W), molybdenum (Mo), tantalum (Ta), ruthenium (Ru), cobalt (Co), copper (Cu), and rhodium (Rh), dielectric and semiconductor materials such as, but not limited to, nitrides of metals and semiconductors such as titanium nitride (TiN), tantalum nitride, (TaN) silicon nitride (Si₃N₄), molybdenum nitride (MoN), tungsten nitride (WN, W₂N, WN₂), oxides of metals and semiconductors such as silicon oxide (SiO₂), titanium oxide (TiO), aluminum oxide (Al₂O₃), silicides of metals and semiconductors such as tungsten silicide (W₅Si₃), molybdenum silicide (MoSi₂), titanium silicide (Ti₅Si₃), metal fluorides, and other types of metal, dielectric, and semiconductor targets. The resulting sputter plume 140 is formed by a plasma of the target material.

The ion beam 120 strikes the target 114 at such an angle so that the sputter plume 140 generated from the target 114 travels towards the substrate assembly 106 and the substrate 116. In some configurations of the ion beam system 100, the sputter plume 140 is divergent as it travels from the target 114 towards the substrate assembly 106 and may partially overspray the substrate 116. However, in other configurations, the sputter plume 140 may be made more or less concentrated so that its resulting deposition of material is more effectively distributed over a particular area of the substrate 116.

The substrate assembly 106 is located and oriented such that the sputter plume 140 strikes the substrate 116 at a desired angle as well. In one example configuration of the ion beam system 100, the substrate assembly 106 is attached to a fixture 118 that allows the substrate assembly 106 to be moved in a desired manner, including rotation of the substrate assembly 106 about its axis 119 or pivoting the fixture 118 to tilt the substrate 116 to alter its angle with respect to the sputter plume 140.

The grids 110 of the ion beam source 102 direct the ion beam 120 to the target assembly 104. In one configuration of the ion beam system 100, the grids 110 steer the ion beamlets such that the ion beam 120 is divergent from the centerline axis 125 of the ion beam source 102, compared to if no bulk ion beam steering was provided. In an alternate configuration, the grids 110 steer the ion beamlets such that the ion beam 120 is not divergent from the centerline axis 125. Other constructions and configurations may also be provided. The grids 110 can cause the ion beam 120 to have a symmetric or asymmetric cross-sectional profile around a beam axis. Additionally information regarding beamlet steering is provided in U.S. Pat. No. 8,309,937 (Kameyama).

As mentioned above, the grids 110 have holes or apertures therethrough to allow the beamlets of the ion beam 120 to pass through the grids 110. The individual holes in the grids 110 may be positioned to yield the highest density of holes per area to maximize ions extracted from the ion source 102. Alternatively, the individual holes can be positioned to generate uniform ion beam density profile. Information regarding hole positioning is provided in, e.g., U.S. Pat. No. 7,716,021 (Kameyama).

The grids 110 may have a rectilinearly, elliptically, or non-symmetrically shaped pattern of holes.

As indicated above, the system 100 shown is a generic and generalized system. The system 100 may include any additional features, such as a reactive gas source, an assist ion source, an assist gas source, various heaters, neutralizers, turrets for multiple rotational targets, and diagnostic probes and sensors.

The system 100 may operate at any conventional operating parameters under any operating conditions. For example, the system 100 may be under inert atmosphere, may have a reactive gas added and/or a noble gas. For example, introduction of gases may be as low as 1 sccm to as high as 100 sccm. The system 100 typically operates at a process (chamber) pressure of less than 10⁻³ Torr, e.g., 1×10⁻⁵ to 1×10⁻³ Torr. The system 100, particularly the ion beam source 102, can utilize a high energy ion beam, e.g., having a voltage ranging from less than 100 V (e.g., 40 V) to 2000 V. The system can provide a net deposition or etch rate greater than 10 angstroms/minute, sometimes greater than 100 Å/minute.

Depending on the operating parameters, not all of the sputter plume 140 impinges on the target 114. Rather, the atmosphere of the enclosure or process chamber of the system 100 has plasma ions scattered or deflected, resulting in these plasma ions impinging on some components of the system 100.

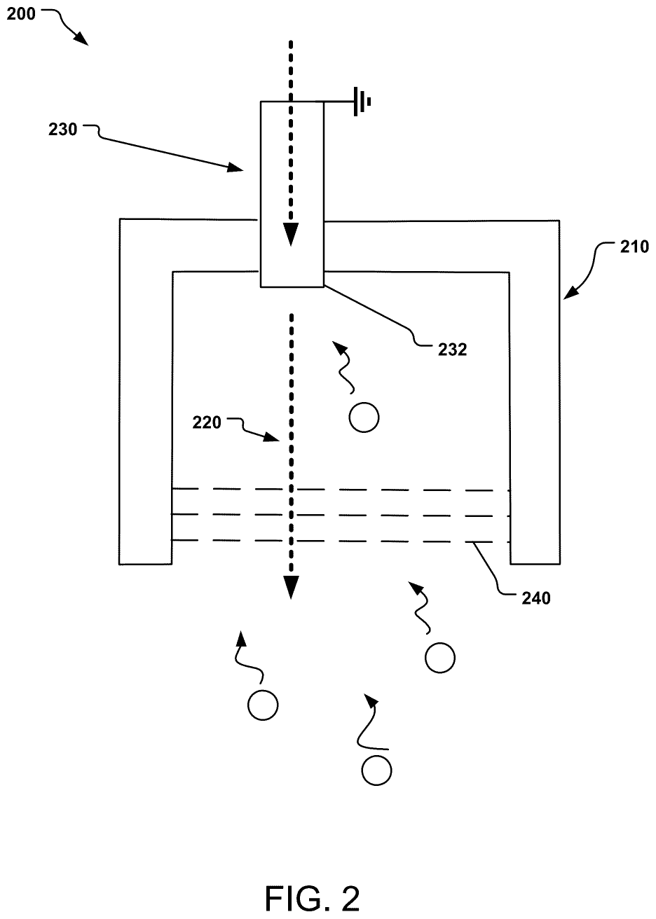

FIG. 2 illustrates a generic, example ion source 200 used in an ion beam system, such as the system 100 of FIG. 1. The ion source 200 includes a discharge chamber 210 in which an ion beam 220 is generated from a gas source provided by a gas delivery system that includes a gas isolator 230; an inlet end 232 of the gas isolator 230 provides the gas into the chamber 210. Positioned downstream of the chamber 210 is at least one grid 240 having holes or apertures therethrough that forms the downstream boundary of the discharge chamber 210. The grid(s) 240 allow beamlets of the ion beam 220 to pass therethrough.

Specifically, the ion source 200 of FIG. 2 includes three grids 240, a screen grid, an acceleration grid, and a deceleration grid, shown in a cross-sectional view, although it should be understood that different combinations of grids may be used, including configurations having a larger number or a fewer number of grids. In one design, the grids are planar and circular in shape, with each grid having a substantially similar diameter, although other shapes are contemplated, including a concave or a convex dished shape, or a shape including segments with different concave and convex curvatures. As shown in FIG. 2, the three grids 240 are positioned parallel to one another with equal distance between the grids. While the grids are shown positioned parallel to one another and equidistant, this characteristic is not required; for example, in some designs the distance between the first two grids is more or less than the distance between the last two grids.

Plasma is generated in the discharge chamber 210 from gas (e.g., from a noble gas such as argon or from a non-noble gas such as oxygen, nitrogen, or methane) injected via the gas isolator 230 into the chamber 210 via the inlet end 232. The grids 240 extract and accelerate ions from the generated plasma through the grid holes toward the target (e.g., the target 114 in FIG. 1).

As ions pass through holes in the grids 240, the ions collide into the downstream positioned target. As the ions collide with the surface of the target, an amount of material from the target is ejected from the surface of the target and travels toward the substrate, such as the substrate 116 as shown in FIG. 1.

However, an amount of the plasma ions does not reach the target; instead, the ions remain in the discharge chamber plasma, impinging on the inner surfaces of the discharge chamber and other components. Some of the plasma ions return to the ion source 200, even passing through the grids 240 and returning into the chamber 210. In some instances, the ions move from the chamber 210 into and through the inlet end 232 of the gas isolator 230, moving countercurrent to the plasma-generating gas. In the same manner, charged particles that are generated near the gas inlet of the chamber 210 can back stream into the gas inlet end 232 and through the gas isolator 230 to the grounded end, where the particles short to ground, generate arcs and, as a result, potentially extinguishing the plasma.

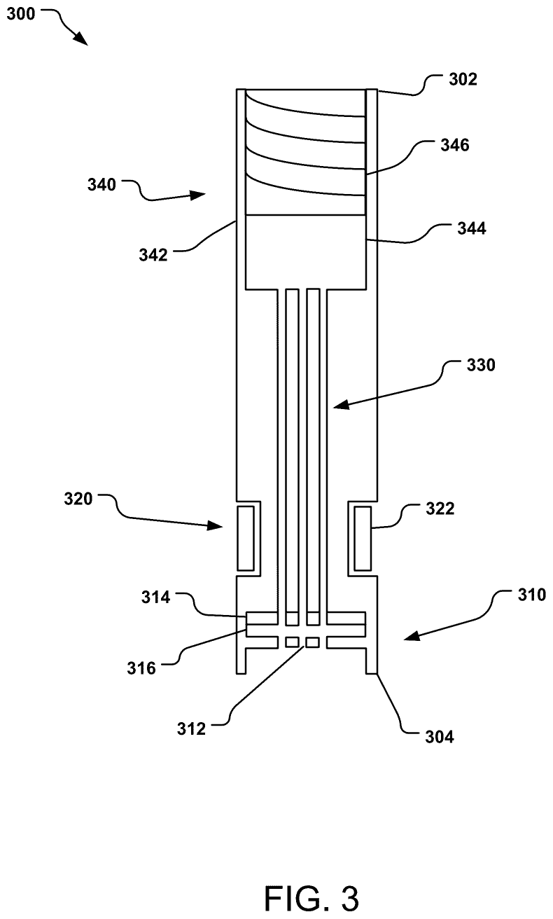

When the ion source 200 is operating at high potential, high pressure and/or high current extraction, the presence of the high density plasma in the gas isolator 230 results in electrical breakdown, which leads to plasma loss and damage to the gas delivery system, as well as other components of the ion source 200. FIG. 3 provides a design for a gas isolator that inhibits encroachment of plasma to the gas delivery system.

Turning to FIG. 3, another gas isolator 300 is shown, suitable for use as part of a gas delivery system. The gas isolator 300 is oriented in the figure to have the gas flow from top down, as in FIG. 2.

The gas isolator 300 has a first end 302 which is a high pressure, grounded side, and a second end 304, which is a low pressure, high electrical potential (e.g., greater than 100V, in some embodiments greater than 500V, in other embodiments greater than 1000V) side, with a gas path therethrough. In use, gas flow is from the first end 302 to the second end 304, and thus the first end 302 could be referred to as an inlet end and the second end 304 as an outlet end; the second end 304 provides the inlet for the gas into the chamber, as shown in FIG. 2. Proximate the first end 302 is a gas source (not shown) that provides the process gas (e.g., a noble gas such as argon or a non-noble gas such as oxygen, nitrogen, or methane) to the gas isolator 300.

The design of the gas isolator 300 creates an insulating barrier or gap between the high voltage components to which gas is supplied (e.g., the discharge chamber) and grounded gas supply lines that provide the process gas to the isolator 300, thus inhibiting electrical breakdown in the system. The design of the gas isolator utilizes at least one of several approaches to maintain the plasma at high potential: maximizing the path length to the grounded gas supply line, having electrically insulating material with high dielectric constant in the path, cavities to limit the mean free path of the charged particles, having a path with a high aspect ratio to maximize the probability of charged particle neutralization upon impinging onto the dielectric material surface, utilizing off-axis aperture patterns to define a portion (e.g., inlet) of the path, and applying a transverse magnetic field across the path. Depending on the application, all or only some of these features might be incorporated into the gas isolator.

The gas isolator 300 is designed with at least a long path therethrough, including a tortuous path section, a transverse magnetic field to suppress arc formation, and a large neutralization surface area. The path through the gas isolator 300, from the first end 302 to the second end 304 has a high aspect ratio, e.g., at least a 1:50 aspect ratio, or a 1:200 aspect ratio, and even as much as a 1:300 aspect ratio. This long path reduces the likelihood of a charged particle, having entered the isolator 300 at the first end 302, from reaching the low potential gas source (not shown) proximate the first end 302. The transverse magnetic field decreases the mean free path of the charged particles and deflects the particles towards a neutralizing surface, extinguishing or suppressing electron avalanche formation. The gas isolator 300 also includes a tortious path proximate the first end 302, to yet further inhibit charged particles from reaching the gas source.

Turning to the details shown in FIG. 3, proximate the second end 304, which would be the inlet for any charged particles entering the gas isolator 300, is an aperture array region 310, which includes a primary array 312, a secondary array 314, and an ion trap cavity 316 therebetween. The arrays 312, 314 have a plurality of apertures or holes therethrough. The apertures or holes in the primary and secondary arrays 312, 314 can have different relative positions or diameters, fully or partially off-axis. Extending from the apertures in the secondary array 314 are a plurality of elongate paths 330; in some embodiments, one path 330 extends from each aperture. In the figure, the paths 330 are shown essentially straight, but in alternate embodiments may be curved or have an indirect path. At a location along the paths 330, is a transverse, magnetized region 320 provided by at least one magnet 325. The paths 330 lead to a tortuous region 340 having a flow path therethrough, the path at least partially including electrically insulating or nonconductive material. At the first end 302 of the gas isolator 300 is the grounded side of gas delivery system. Thus, any ion that may enter at the second end 304 would have to follow a path through the array region 310, along the elongated paths 330 through the magnetized region 320, and then through the tortuous region 340.

As indicated above, the array region 310 includes the apertures of the primary array 312, the apertures of the secondary array 314, and the ion trap cavity 316 therebetween.

The primary array 312 is the first point of contact with any plasma and includes at least one, but typically a plurality of, holes or apertures therethrough that allow the process gas to pass therethrough yet inhibit plasma from passing therethrough. The plasma facing surface of the primary array 312 is at a high positive potential, due to its orientation to the components of the system; because of the high positive potential, the primary array 312 may act as a single grid system and accelerate an uncollimated beam of charged particles towards grounded surfaces. The apertures of the primary array 312 may be any shape, arranged in any pattern. The radius of the apertures (or a similar dimension for non-circular apertures) should be less than the Debye length of the plasma, to eliminate large plasma leakage. Example dimensions for the apertures include 0.2 mm, 0.5 mm, 1 mm or more.

The secondary array 314 includes at least one, but typically a plurality of, holes or apertures therethrough that allow the process gas to pass therethrough yet inhibit plasma from passing therethrough. The apertures of the secondary array 314 provide an indirect or off-axis pass through for any already neutral gas species. The apertures of the secondary array 314 may be any shape, arranged in any pattern; the aperture size, location and separation between adjacent apertures can be optimized to block the charged particles travelling back toward the first end 302. Example dimensions for the apertures include 0.2 mm, 0.5 mm, 1 mm or more.

The ion trap cavity 316 between the arrays 312, 314 serves as the primary neutralization space for any ions that enter. The ion trap cavity 316 defines the distance/gap between the apertures of the primary array 312 and the apertures of the secondary array 314. This distance, which can also be referred to as the depth of the cavity 316, is equal to or smaller than (also referred to as no more than) the mean free path of the charged particles, at the pressure in the ion trap cavity. The mean free path is the path distance that a particle can theoretically move before colliding with another particle. Example depths for the ion trap cavity 316 include 0.2 mm, 0.5 mm, 1 mm or more. By having the depth of the ion trap cavity 316 the same or less than the mean free path, the charged ions that enter the cavity 316 will not go through any scattering event but will follow a straight path.

Because the ions follow a straight path through the cavity 316, they impinge on the surface of the secondary array 314 rather than pass through an aperture of the secondary array 314, because the apertures in the primary array 312 (through which an ions do pass) and the apertures in the secondary array 314 are offset (i.e., axially offset in relation to a longitudinal axis of the gas isolator 300 running from the first end 302 to the second end 304). By having the apertures of the arrays 312, 314 offset, a straight path through the array region 310 is avoided.

Proximate to the array region 310, particularly to the secondary array 314, is the plurality of elongate paths 330. A path 330 may have any cross-sectional shape, either the same or different than the aperture from which it extends. Different paths may have different cross-sectional shapes or, even, paths (e.g., one path may be straight, and another path may be curved).

To obtain maximum neutralization surface in the gas isolator 300, the paths 330 between the hole-array region 310 and the tortuous path region 340 have a high aspect ratio, often at least a 1:50 aspect ratio. Example dimensions include 0.5 mm diameter with a 5 cm length (a 1:100 aspect ratio), and a 0.5 mm diameter with a 4 cm length (a 1:80 aspect ratio).

Although the paths 330 are shown as being straight in FIG. 3, the paths 330 may have one or more curves along their length. Right angles or acute angles in the paths 330 are possible as well.

At a location along the paths 330 is a transverse, magnetized region 320 provided by at least one magnet 325. The magnet 322 provides a transverse magnetic field across the paths 330 that inhibits charged particle motion in the direction perpendicular to the field. The magnet 322 may be a high temperature permanent magnetic (e.g., having a Curie temperature of at least 100° C.) or an electromagnet. Example strength for the magnet 322 are greater than 2500 Gauss, in some embodiments greater than 5000 Gauss. The magnet 322 induces a cycloid motion to the charged particles that pass through the apertures of the primary and secondary arrays 312, 314. The magnetic field suppresses arc formation by stopping electrons from gaining energy, through acceleration in the electric potential gradient.

At the end of the paths 330, opposite the array region 310, is the tortuous path region 340 formed by a body 342. The body 342 can be formed from any electrically insulating or dielectric material that can withstand the temperature, outgassing, and breakdown voltage. Examples of suitable ceramic materials include alumina, quartz, sapphire, or a machinable ceramic such as Macor® glass ceramic. This body 342 can also be present at and/or form parts or all of the array region 310, the paths 330, the magnetized region 320, etc.

The body 342 has an internal chamber 344 that can have an electrically insulating material therein to provide a tortuous path through the chamber 344, such as insulating foam or insulating beads or ceramic spiral or other shapes with increased effective surface area. Adjacent to the chamber 344 is another tortuous path 346, in this design, a spiral path. The spiral path elongates the traveled path for any remaining charged particles, maximizing the ground potential distance, and provides a large surface area for neutralization. Right angles or acute angles in the tortuous path region 340 can be used.

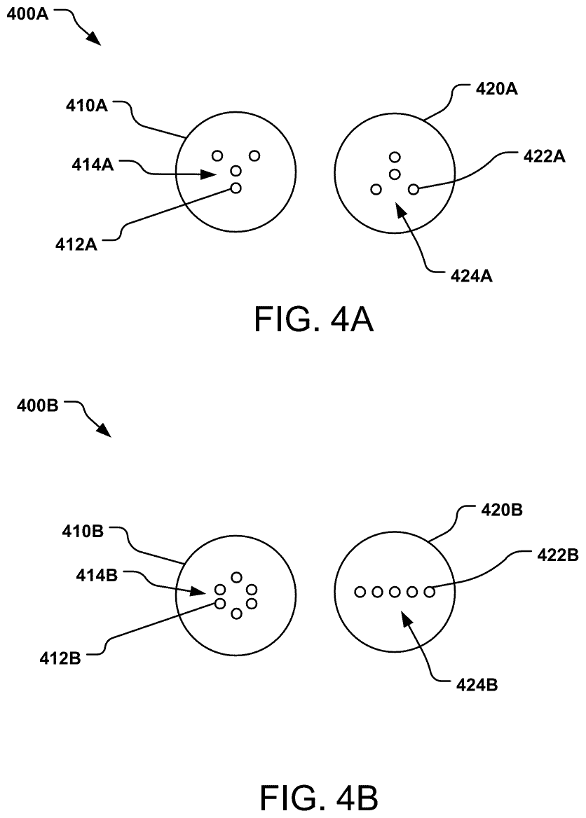

Described above is an overall gas isolator that forms part of a gas delivery system for an ion beam system. Variations to the design shown in FIG. 3 can, of course, be made. Two example sets of aperture arrays, such as the arrays 312, 314 of FIG. 3, are shown in FIGS. 4A and 4B.

FIG. 4A shows a set 400A having a primary array 410A and a secondary array 420A. The primary array 410A has a plurality of apertures 412A in a pattern 414A and the secondary array 420A has a plurality of apertures 422A in a pattern 424A. In this set 400A, the pattern 414A and the pattern 424A have the same arrangement of apertures 412A, 422A, although the patterns 414A, 424A are positioned so that the apertures 412A of the primary array 410A are offset from the apertures 422A of the secondary array 420A. In this example, the patterns 414A, 424A are offset (e.g., rotated) either 60 degrees or 180 degrees in respect to each other, so that none of the apertures 412A, 422A overlie each other.

FIG. 4B shows a set 400B having a primary array 410B and a secondary array 420B. The primary array 410B has a plurality of apertures 412B in a pattern 414B and the secondary array 420B has a plurality of apertures 422B in a pattern 424B. In this set 400B, the pattern 414B and the pattern 424B have a different arrangement of apertures 412B, 422B, particularly, the pattern 414B has the apertures 412B arranged in a circle and the pattern 424B has the apertures 422B arranged in a line. Because the patterns are different, at least some of the apertures are offset, although not necessarily all are.

The arrays 410, 420 may take the form of discs, slides, screens, or other element having a diameter significantly greater than its thickness through which the apertures 412A, 422A, 412B, 422B are formed. Typically, the arrays 410, 420 have a shape that corresponds to the cross-sectional shape of the gas isolator.

Although only two hole-arrays are shown as forming a set, a set may be formed by three or more hole-arrays. Typically, as the number of arrays increases, so does the resistance to charged particle introduction through the gas isolator and into the gas inlet.

From the foregoing, it will be appreciated that specific embodiments of the invention have been described herein for purposes of illustration, but that various modifications may be made without deviating from the scope of the invention. Accordingly, the invention is not limited except as by the appended claims.

Although the technology has been described in language that is specific to certain structures and materials, it is to be understood that the invention defined in the appended claims is not necessarily limited to the specific structures and materials described. Rather, the specific aspects are described as forms of implementing the claimed invention. Because many embodiments of the invention can be practiced without departing from the spirit and scope of the invention, the invention resides in the claims hereinafter appended.

Various features and details have been provided in the multiple designs described above. It is to be understood that any features or details of one design may be utilized for or with any other design, unless contrary to the process, construction or configuration. Any variations may be made. For example, processing time, pressure, temperature, etc. may be varied.

The above specification and examples provide a complete description of the structure and use of exemplary implementations of the invention. The above description provides specific implementations. It is to be understood that other implementations are contemplated and may be made without departing from the scope or spirit of the present disclosure. The above detailed description, therefore, is not to be taken in a limiting sense. While the present disclosure is not so limited, an appreciation of various aspects of the disclosure will be gained through a discussion of the examples provided.

Unless otherwise indicated, all numbers expressing feature sizes, amounts, and physical properties are to be understood as being modified by the term “about,” whether or not the term “about” is immediately present. Accordingly, unless indicated to the contrary, the numerical parameters set forth are approximations that can vary depending upon the desired properties sought to be obtained by those skilled in the art utilizing the teachings disclosed herein.

As used herein, the singular forms “a”, “an”, and “the” encompass

implementations having plural referents, unless the content clearly dictates otherwise. As used in this specification and the appended claims, the term “or” is generally employed in its sense including “and/or” unless the content clearly dictates otherwise.

Spatially related terms, including but not limited to, “bottom,” “lower”, “top”, “upper”, “beneath”, “below”, “above”, “on top”, “on,” etc., if used herein, are utilized for ease of description to describe spatial relationships of an element(s) to another. Such spatially related terms encompass different orientations of the device in addition to the particular orientations depicted in the figures and described herein. For example, if a structure depicted in the figures is turned over or flipped over, portions previously described as below or beneath other elements would then be above or over those other elements.

What is claimed is:

1. A high-potential gas isolator for an ion beam system, the gas isolator comprising:
an electrically insulating body having a first end and an opposite second end with a flow path from the first end to the second end, the flow path extending through an aperture array region having a plurality of axially offset apertures, a magnetized region, and a tortuous path region, with the magnetized region operably in the flow path between the aperture array region and the tortuous path region.

2. The gas isolator of claim 1, wherein the aperture array region comprises a first array having a first plurality of apertures and a secondary array having a second plurality of apertures, the first plurality axially offset from the second plurality, and an ion trap cavity between the first array and the secondary array.

3. The gas isolator of claim 2, wherein the ion trap cavity has a depth between the first array and the secondary array that is no greater than a mean free path for an energized ion.

4. The gas isolator of claim 2, wherein the first plurality of apertures are arranged in a first pattern and the second plurality of apertures are arranged in a second pattern different than the first pattern.

5. The gas isolator of claim 2, wherein the first plurality of apertures are arranged in a pattern and the second plurality of apertures are arranged in the pattern, with the second plurality of apertures rotated in relation to the first plurality of apertures.

6. The gas isolator of claim 1, wherein the flow path has an aspect ratio of at least 1:100.

7. The gas isolator of claim 6, wherein the flow path has an aspect ratio of at least 1:200.

8. The gas isolator of claim 1, wherein the tortuous path region includes a spiral path.

9. The gas isolator of claim 1 wherein an elongate path is present in the magnetized region, the magnetized region providing a transverse magnetic field across the elongate path.

10. The gas isolator of claim 9, wherein the tortuous path has an aspect ratio of at least 1:100.

11. A high-potential gas isolator for an ion beam system, the gas isolator comprising:
an electrically insulating body having a first grounded end and a second high potential end with a longitudinal flow path through the body, the flow path extending through:
an aperture array region having a plurality of longitudinally spaced and axially offset apertures,
a magnetized region, and
a tortuous path region.

12. The gas isolator of claim 11, wherein the magnetized region is present between the aperture array region and the tortuous path region.

13. The gas isolator of claim 11, wherein the tortuous path is proximate the first grounded end and the aperture array region is proximate the second high potential end.

14. The gas isolator of claim 11, wherein the aperture array region comprises a first array having a first plurality of apertures and a secondary array having a second plurality of apertures, the first plurality axially offset from the second plurality, and an ion trap cavity between the first array and the secondary array.

15. The gas isolator of claim 14, wherein the ion trap cavity has a depth between the first array and the secondary array that is no greater than a mean free path for an energized ion.

16. The gas isolator of claim 14, wherein the first plurality of apertures are arranged in a first pattern and the second plurality of apertures are arranged in a second pattern different than the first pattern.

17. The gas isolator of claim 14, wherein the first plurality of apertures are arranged in a pattern and the second plurality of apertures are arranged in the pattern, with the second plurality of apertures rotated in relation to the first plurality of apertures.
